(19) United States
(12) Patent Application Publication
(10) Pub. No.: US 2015/0258585 A1
(43) Pub. Date: Sep. 17, 2015

(54) CLEANING APPARATUS AND PROCESS FOR CLEANING ELECTRONIC COMPONENTS

(71) Applicant: DONG GUAN COWELL OPTIC ELECTRONICS LIMITED, Dongguan City (CN)

(72) Inventor: Gun Woo PARK, Dongguan (CN)

(21) Appl. No.: 14/214,869

(22) Filed: Mar. 15, 2014

(51) Int. Cl. B08B 7/00; H01J 37/32

(52) U.S. Cl. CPC B08B 7/0035; H01J 37/32009; H01J 37/32733; H01J 37/32899

(57) ABSTRACT

Cleaning apparatuses for cleaning electronic components such as camera modules and electronics substrates are provided. The cleaning apparatuses have a plurality of processing zones and one or more conveyors for conveying an electronic component to each processing zone sequentially such that the electronic component is processed in-line by the processing zones. In one aspect, plasma is applied to the electronic component at atmospheric pressure at one of the processing zones. In another aspect, there is a plurality of separately controlled conveyors, and the electronic component is processed at each processing zone over a respective processing time, with at least one of the processing times being different to the other processing times.

### FIELD OF THE INVENTION

The present invention relates to cleaning apparatuses and processes for cleaning electronic components such as camera modules and electronics substrates.

### BACKGROUND OF THE INVENTION

Prior cleaning processes typically utilize a plurality of cleaning stations with each performing an aspect of the cleaning process. One problem with these prior processes is that the electronic component being cleaned needs to be manually passed from one station to the next by a process worker. These prior processes are therefore inefficient, decreasing throughput and yield. Another problem is that the handling of the electronic component between stations further contaminates the electronic component with dirt, dust, and other contaminants.

It is an object of the present invention to overcome or ameliorate at least one of the disadvantages of the prior art, or to provide a useful alternative.

### SUMMARY OF THE INVENTION

The present invention provides, in a first aspect, a cleaning apparatus for cleaning an electronic component, the cleaning apparatus comprising:

a plurality of processing zones; and

one or more conveyors for conveying the electronic component to each processing zone sequentially such that the electronic component is processed in-line by the processing zones;

wherein at one of the processing zones, plasma is applied to the electronic component at atmospheric pressure.

In a second aspect, the present invention provides a cleaning process fear cleaning an electronic component, the cleaning process comprising:

conveying the electronic component to a plurality of processing zones sequentially such that the electronic component is processed in-line by the processing zones;

processing the electronic component at each processing zone in-line; and

applying plasma to the electronic component at atmospheric pressure at one of the processing zones.

The present invention also provides, in a third aspect, a cleaning apparatus for cleaning an electronic component, the cleaning apparatus comprising:

a plurality of processing zones, the electronic component being processed at each processing zone over a respective processing time, with at least one of the processing times being different to the other processing times; and

a plurality of separately controlled conveyors for conveying the electronic component to each processing zone sequentially such that the electronic component is processed in-line by the processing zones.

In a fourth aspect, the present invention provides a cleaning process for cleaning an electronic component, the cleaning process comprising:

separately controlling a plurality of conveyors to convey the electronic component to each one of a plurality of processing zones sequentially such that the electronic component is processed in-line by the processing zones; and

processing the electronic component at each processing zone over a respective processing time, with at least one of the processing times being different to the other processing times.

Further features of the present invention are defined in the appended claims. It will be appreciated that features may be combined in various combinations in various embodiments of the present invention.

Throughout this specification, including the claims, the words “comprise”, “comprising”, and other like terms are to be construed in an inclusive sense, that is, in the sense of “including, but not limited to”, and not in an exclusive or exhaustive sense, unless explicitly stated otherwise or the context clearly requires otherwise.

### BRIEF DESCRIPTION OF THE FIGURES

Preferred embodiments in accordance with the best mode of the present invention will now be described, by way of example only, with reference to the accompanying figures, in which:

FIG. 1 is a schematic plan view of a cleaning apparatus in accordance with an embodiment of the present invention;

FIG. 2 is a schematic side view of a cleaning apparatus in accordance with an embodiment of the present invention;

FIG. 3 is a schematic side view of a cleaning apparatus in accordance with another embodiment of the present invention;

FIG. 4 is a schematic side view of a cleaning apparatus in accordance with another embodiment of the present invention;

FIG. 5 is a schematic plan view of a cleaning apparatus in accordance with another further embodiment of the present invention; and

FIG. 6 is a schematic plan view of a cleaning apparatus in accordance with a further embodiment of the present invention.

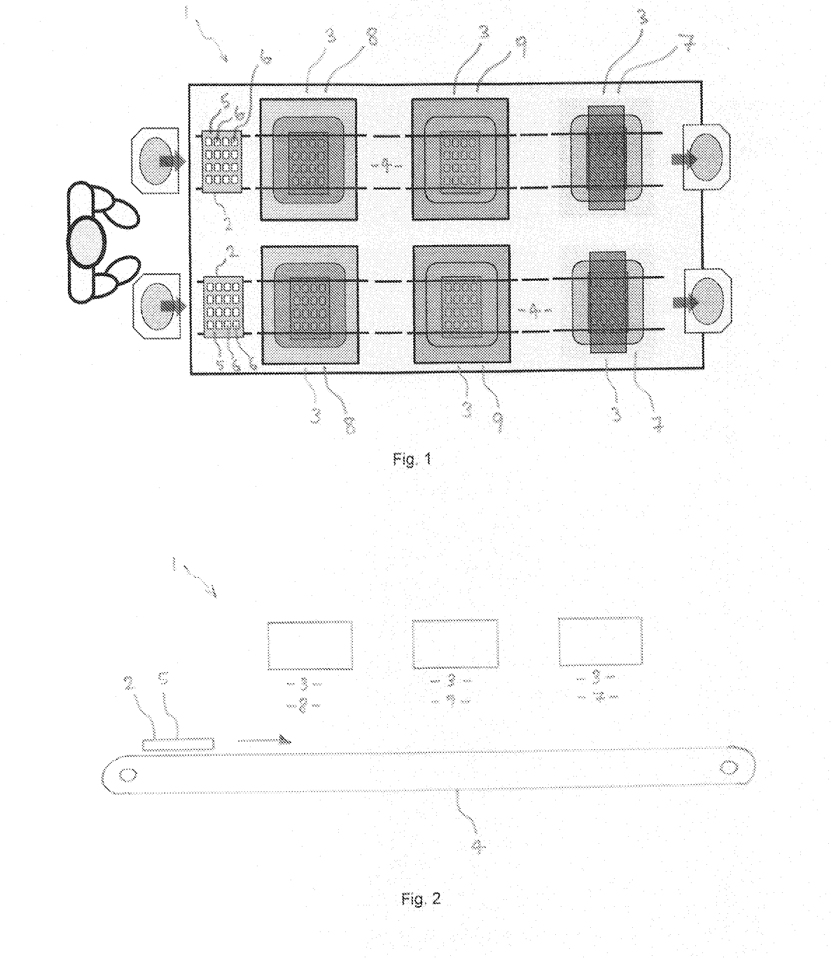

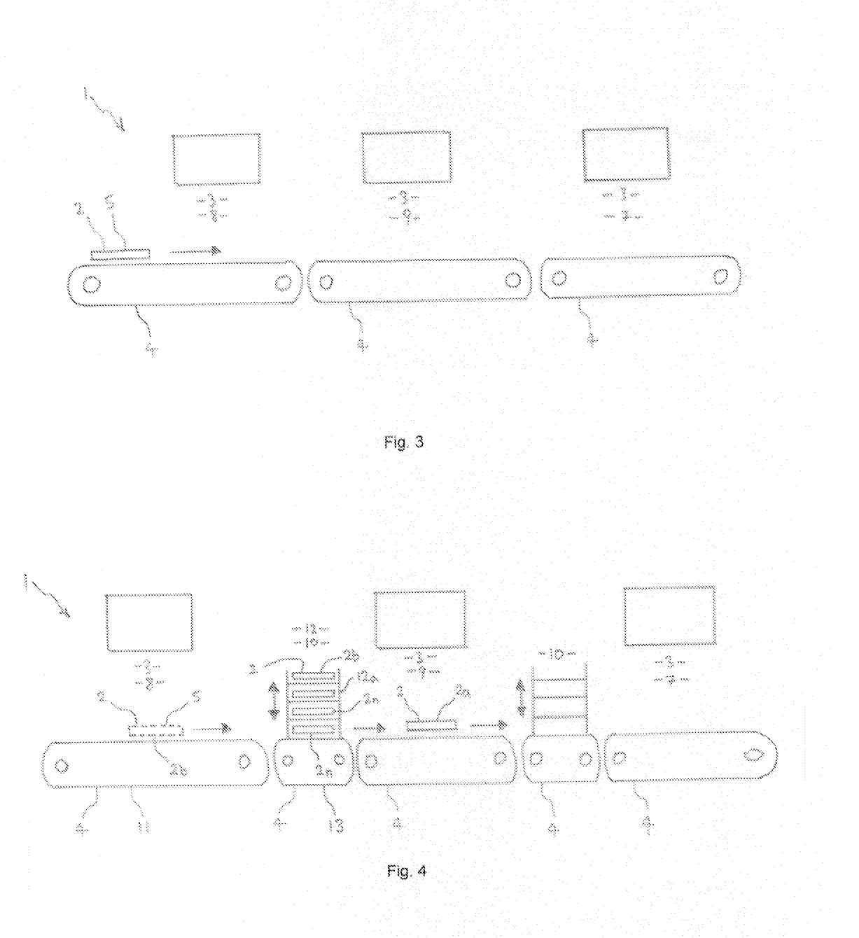

### DETAILED DESCRIPTION

Referring to the figures, there is provided a cleaning apparatus 1 for cleaning an electronic component 2. The cleaning apparatus comprises a plurality of processing zones 3, and one or more conveyors 4 for conveying the electronic component 2 to each processing zone 3 sequentially such that the electronic component is processed in-line by the processing zones.

The electronic component 2 can be electronics substrates, ceramic substrates, camera modules, components for OLED and LED display panels. The electronic component 2 can also be a plurality of electronic components. As an example, and as depicted in the figures, this can be in the form of a magazine 5 holding an array of electronics substrates 6, or an array of camera modules. It is also appreciated that items other than electronic components can also be cleaned with the cleaning apparatuses and processes described herein where appropriate.

In accordance with one aspect of the present invention, plasma is applied to the electronic component 2 at atmospheric pressure at one of the processing zones 7. This processing zone is referred to as the plasma zone. Another of the processing zones is a blowing zone 8 where a gas is blown onto the electronic component to displace contaminants away from the electronic component. The gas can be air, nitrogen (N₂), or any other suitable gas. Yet another of the processing zones is a vacuum zone 9 where a vacuum is applied to the electronic component to remove contaminants away from the electronic component. The vacuum zone is before the plasma zone, and the blowing zone is before the vacuum zone. That is, the electronic component 2 is conveyed to the blowing zone first, the vacuum zone second, and the plasma zone third. In one embodiment, deionized water (DIW) is also applied to the electronic component at the plasma zone 7.

The plasma zone 7 applies plasma at atmospheric pressure instead of at vacuum pressure which was what was done prior to the present invention. This has the important advantage that the plasma zone is not required to be a separate unit, which was required to provide an environment under vacuum pressure, as was the case in the past. The separate vacuum unit was typically required to be sealed. This complicated the cleaning process since the pressure inside the separate vacuum unit needed to brought back to atmospheric before the electronic component 2 being cleaned could be placed inside the unit so that plasma could be applied. Once inside the separate vacuum unit, the pressure would need to be decreased to create vacuum pressure. The plasma would then be applied, and once this was complete, the separate vacuum unit would then need to be brought back to atmospheric pressure before the electronic component 2 could be removed.

In other embodiments, combinations of the above processes, or other processes, can be combined in the same zone. For example, blowing gas onto the electronic component and applying a vacuum to the electronic component can be combined in the same zone. Similarly, the process described at one zone above can be split into separate zones. For example, the application of DIW can occur in a zone separate to the plasma zone. In other embodiments, one or more of the processes or zones described above can be omitted. In yet other embodiments, other suitable processes can be added, either in a separate zone or in combination with other processes in the same zone.

The processing zones 3 can be integrated as a single machine. This includes a single machine made from separate modular stations that correspond to the processing zones 3 which are combined together to form the single machine. This also includes a unitary machine having portions that respectively perform the processes corresponding to the processing zones 3.

The processing zones 3 and one or more of the conveyors 4 can also be integrated as a single machine. Again, this includes a single machine made from separate modular stations that correspond to the processing zones 3 and one or more conveyors 4 which are combined together to form the single machine, and a unitary machine having portions that respectively perform the processes corresponding to the processing zones 3 and portions in the form of one or more conveyors 4.

The processing zones 3 and one or more of the conveyors 4 can be enclosed in a controlled clean environment, such as clean room. Since the plasma zone 7 is at atmospheric pressure and therefore does not require a separate vacuum enclosure, there is no need for a process worker to enter the controlled clean environment.

The present invention also provides in another aspect, a cleaning process for cleaning an electronic component. Embodiments of the cleaning process can be appreciated from the foregoing description. For example, in one embodiment, the cleaning process comprises conveying the electronic component 2 to a plurality of processing zones 3 sequentially such that the electronic component is processed in-line by the processing zones, and processing the electronic component 2 at each processing zone 3 in-line. The cleaning process also comprises applying plasma to the electronic component 2 at atmospheric pressure at one of the processing zones 7.

In another embodiment, the cleaning process comprises applying a vacuum to the electronic component 2 at one of the processing zones 9 before applying plasma to the electronic component at atmospheric pressure at one of the processing zones 7, and blowing a gas onto the electronic component at one of the processing zones 8 before applying a vacuum to the electronic component at one of the processing zones.

Further features and other embodiments of the cleaning process can be appreciated from the foregoing description.

Different embodiments of the cleaning apparatus 1 can have one or more conveyors 4. In embodiments with a plurality of conveyors, each conveyor 4 can be separately controlled. This specific feature leads to another aspect of the present invention.

In particular, in accordance with another aspect of the present invention, and referring to the figures, there is provided a cleaning apparatus 1 for cleaning an electronic component 2. The cleaning apparatus 1 comprises a plurality of processing zones 3. The electronic component 2 is processed at each processing zone 3 over a respective processing time, with at least one of the processing times being different to the other processing times. The cleaning apparatus 1 has a plurality of separately controlled conveyors 4 for conveying the electronic component 2 to each processing zone 3 sequentially such that the electronic component is processed inline by the processing zones.

The cleaning apparatus 1 comprises one or more buffer zones 10. One or more of the separately controlled conveyors 4 conveys the electronic component 2 to a buffer zone 10 after leaving a processing zone 3 to wait until a next processing zone 3 is ready to receive the electronic component 2. For example, a conveyor 11 conveys the electronic component 2b from the blowing zone 8, Since the processing time at the vacuum zone 9 is longer than the processing time at the blowing zone 8, the electronic component 2a that preceded the electronic component 2b is still being processed at the vacuum zone 9. Therefore, vacuum zone 9 is not yet ready to receive electronic component 2b. Accordingly, the conveyor 11 conveys the electronic component 2b to a buffer zone 12 where the electronic component 2b waits until vacuum zone 9 is ready.

Buffer zone 12 is in the form of a vertical stacker 12a for stacking a plurality of the electronic components 2 in a vertical stack, as shown in FIG. 4. Conveyor 11 conveys electronic component 2b to the first level of the vertical stack. If successive electronic components 2n emerging from the blowing zone 8 also need to wait then conveyor 11 also conveys these electronic components 2n to the vertical stacker in buffer zone 12. Electronic component 2b would then be elevated to higher levels of the vertical stack as successive electronic components 2n are stacked beneath electronic component 2b. When electronic component 2a leaves the vacuum zone 9, vacuum zone 9 becomes ready to receive another electronic component. A conveyor 13 in the buffer zone 12 beneath the vertical stack conveys the electronic component 2 on the first level of the vertical stack to the vacuum zone 9. Alternatively, the conveyor 13 could convey the electronic component 2 on the first level to another conveyor which then conveys the electronic component to the vacuum zone. FIG. 4 shows the arrangement after electronic component 2b has been elevated to the highest level of the vertical stacker 12a with successive electronic components 2n stacked beneath electronic component 2b. Electronic component 2b shown in dotted outline in blowing zone 8 shows the position of electronic component 2b before electronic component 2b has been conveyed by conveyor 11 to the buffer zone 12.

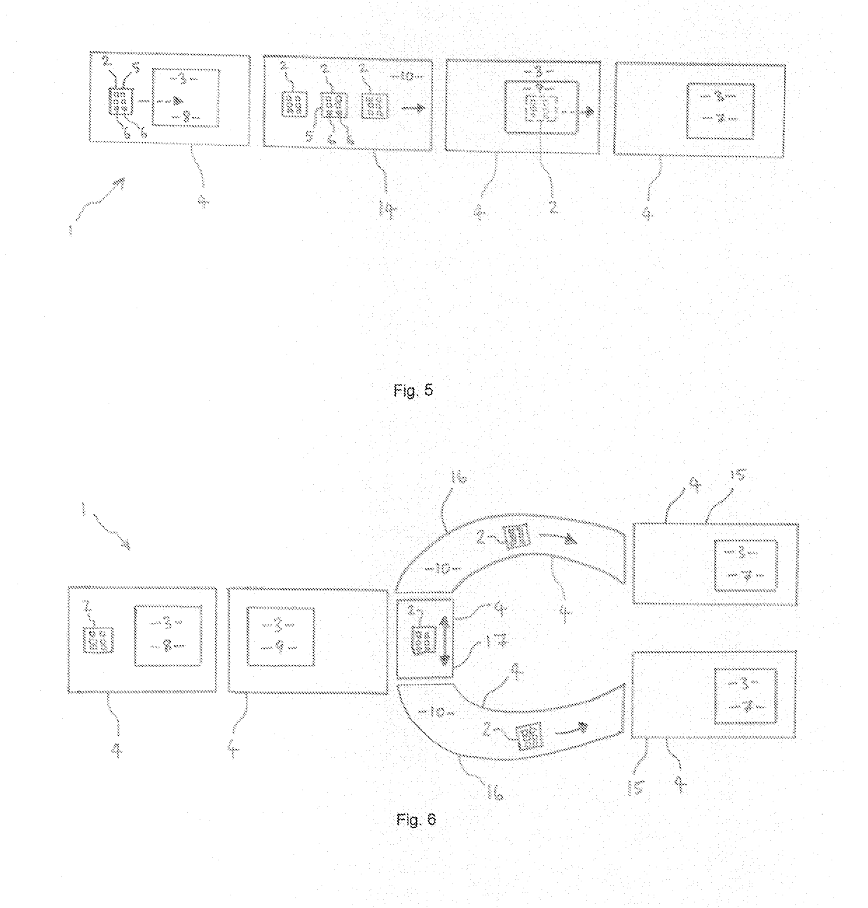

In another embodiment, as shown in FIG. 5, one or more of the buffer zones 10 is in the form of a conveyor 14 having a length accommodating a plurality of the electronic components 2 in a queue. The electronic components 2 accumulate in the queue until the next processing zone 3 is ready to receive the next electronic component.

The cleaning apparatus 1 can have one or more buffer zones 10. One or more of these can be in the form of a vertical stacker similar to buffer zone 12 described above, or in the form of a conveyor 14 as described above. Embodiments of the cleaning apparatus can also have a combination or vertical stackers 12 or conveyors 14.

Furthermore, the cleaning apparatus 1 can include a plurality of the same type of processing zone operating in parallel with each other. For example, as shown in FIG. 6, if the plasma zone 7 has a longer processing time than the preceding vacuum zone 9, the cleaning apparatus can have a plurality of plasma zones 7 and a plurality of respective conveyors 15. As successive electronic components 2 are processed by the vacuum zone 9, the electronic components 2 are conveyed by different branch conveyors 16 to different plasma zones 7. A transfer conveyor 17 selectively conveys the electronic components 2 to the appropriate branch conveyor 16. The cleaning apparatus 1 could have a sufficient number of plasma zones 7 so that no electronic component 2 needs to wait, that is, there is a sufficient number so the plasma zone that starts processing first will be ready before or immediately after the last plasma zone starts processing. In another embodiment, one or more of the branch conveyors 16 can act as a buffer zone 10, as described above, and in particular, similar to the manner in which the conveyor 14 u described above acts as a buffer zone.

The cleaning apparatus can comprise one or more of the blowing zone 8, vacuum zone 9, and plasma zone 7 described in the earlier aspects above, but not necessarily.

This aspect of the present invention provides the advantage that processing at one processing zone does not need to stop to wait for the completion of processing at the next processing zone This results in much improved efficiency, throughput, and yield.

The present invention also provides in another aspect, a further cleaning process for cleaning an electronic component. Embodiments of this cleaning process can be appreciated from the foregoing description. For example, in one embodiment, the cleaning process comprises separately controlling a plurality of conveyors 4 to convey the electronic component 2 to each one of a plurality of processing zones 3 sequentially such that the electronic component is processed in-line by the processing zones, and processing the electronic component 2 at each processing zone over a respective processing time, with at least one of the processing times being different to the other processing times. Further features and other embodiments of the cleaning process can be appreciated from the foregoing description.

Although the invention has been described with reference to specific examples, it can be appreciated by those skilled in the art that the invention can be embodied in many other forms. Various variants and modifications may be made by those of ordinary skill in the art without departing from the spirit and essence of the invention, and these variants and modifications are also covered within the scope of the invention. It can also be appreciated by those skilled in the art that the features of the various examples described can be combined in other combinations.

1. A cleaning apparatus for cleaning an electronic component, the cleaning apparatus comprising:
a plurality of processing zones; and
one or more conveyors for conveying the electronic component to each processing zone sequentially such that the electronic component is processed in-line by the processing zones;
wherein at one of the processing zones, plasma is applied to the electronic component at atmospheric pressure.

2. A cleaning apparatus according to claim 1 wherein at one of the processing zones, a gas is blown onto the electronic component to displace contaminants away from the electronic component.

3. A cleaning apparatus according to claim 1 wherein at one of the processing zones, a vacuum is applied to the electronic component to remove contaminants away from the electronic component.

4. A cleaning apparatus according to claim 1 wherein another of the processing zones is a blowing zone where a gas is blown onto the electronic component, and another of the processing zones is a vacuum zone where a vacuum is applied to the electronic component, the vacuum zone being before the processing zone where plasma is applied to the electronic component at atmospheric pressure, and the blowing zone being before the vacuum zone.

5. A cleaning apparatus according to claim 1 wherein at the processing zone where plasma is applied to the electronic component at atmospheric pressure, deionized water is also applied to the electronic component.

6. A cleaning apparatus according to claim 1 wherein the processing zones are integrated as a single machine.

7. A cleaning apparatus according to claim 1 wherein the processing zones and one or more of the conveyors are integrated as a single machine.

8. A cleaning apparatus according to claim 1 wherein the processing zones and one or more of the conveyors are enclosed in a controlled clean environment.

9. A cleaning apparatus according to claim 1 comprising a plurality of conveyors, each being separately controlled.

10. A cleaning process for cleaning an electronic component; the cleaning process comprising:
conveying the electronic component to a plurality of processing zones sequentially such that the electronic component is processed in-line by the processing zones;
processing the electronic component at each processing zone in-line; and
applying plasma to the electronic component at atmospheric pressure at one of the processing zones.

11. A cleaning apparatus for cleaning an electronic component, the cleaning apparatus comprising:
a plurality of processing zones, the electronic component being processed at each processing zone over a respective processing time, with at least one of the processing times being different to the other processing times; and
a plurality of separately controlled conveyors for conveying the electronic component to each processing zone sequentially such that the electronic component is to processed in-line by the processing zones.

12. A cleaning apparatus according to claim 11 comprising one or more buffer zones, one or more of the separately controlled conveyors conveying the electronic component to a said buffer zone after leaving a said processing zone to wait until a next said processing zone is ready to receive the electronic component.

13. A cleaning apparatus according to claim 12 wherein at least one buffer zone is in the form of a vertical stacker for stacking a plurality of the electronic components in a vertical stack.

14. A cleaning apparatus according to claim 12 wherein at least one buffer zone is in the form of a conveyor having a length accommodating a plurality of the electronic components in a queue.

15. A cleaning apparatus according to claim 11 wherein at one of the processing zones, plasma is applied to the electronic component at atmospheric pressure.

16. A cleaning apparatus according to claim 15 wherein at the processing zone where plasma is applied to the electronic component at atmospheric pressure, deionized water is also applied to the electronic component.

17. A cleaning apparatus according to claim 11 wherein at one of the processing zones, a gas is blown onto the electronic component to displace contaminants away from the electronic component.

18. A cleaning according to claim 11 wherein at one of the processing zones, a vacuum is applied to the electronic component to remove contaminants away from the electronic component.

19. A cleaning apparatus according to claim 11 wherein one of the processing zones is a blowing zone where a gas is blown onto the electronic component, another of the processing zones is a vacuum zone where a vacuum is applied to the electronic component, and another of the processing zones is a plasma zone where plasma is applied to the electronic component at atmospheric pressure, the blowing zone being before the vacuum zone, and the vacuum zone being before the plasma zone.
